(19) United States
(12) Patent Application Publication
(10) Pub. No.: US 2025/0154961 A1
(43) Pub. Date: May 15, 2025

(54) COOLING FAN CONTROL DEVICE AND COOLING FAN CONTROL METHOD

(71) Applicant: TOSHIBA TEC KABUSHIKI KAISHA, Tokyo (JP)

(72) Inventor: Yasuhiro Katabira, Tagata Shizuoka (JP)

(21) Appl. No.: 18/733,931

(22) Filed: Jun. 5, 2024

(30) Foreign Application Priority Data
Nov. 15, 2023 (JP) 2023-194680

(51) Int. Cl. F04D 27/00; F04D 25/16; G06F 1/20; H05K 7/20

(52) U.S. Cl. CPC F04D 27/004; F04D 25/166; G06F 1/206; H05K 7/20209

(57) ABSTRACT

A cooling fan control device controls an operation of a cooling fan connected to a control microcomputer by communicating with the control microcomputer, and includes a control table reading unit to read a control table in which a control characteristic of the cooling fan is described, the control table being stored in the control microcomputer, a control table storage unit to store a content of the control table read by the control table reading unit, a control parameter acquisition unit to acquire an ambient temperature and a fan speed of the cooling fan that are in association with each other from the control microcomputer, and a control command unit to output a control command for controlling the cooling fan to the control microcomputer based on the ambient temperature and the fan speed acquired by the control parameter acquisition unit, and based on the control table.

### CROSS-REFERENCE TO RELATED APPLICATION

This application is based upon and claims the benefit of priority from Japanese Patent Application No. 2023-194680, filed on Nov. 15, 2023, the entire contents of which are incorporated herein by reference.

### FIELD

Embodiments described herein relate generally to a cooling fan control device and a cooling fan control method.

### BACKGROUND

In related art, a system is proposed in which hardware has a function of controlling a cooling fan and the hardware is controlled by firmware mounted on a controller module.

In such a system in the related art, the cooling fan is controlled by the firmware mounted on the controller module, that is, a type of application program. Therefore, for example, when a type of the cooling fan is changed to a different type, it is necessary to rewrite a content of the application program, resulting in taking time and effort.

### DESCRIPTION OF THE DRAWINGS

FIG. 1 is a perspective view illustrating an example of an electronic device according to an embodiment;

FIG. 2 is a hardware block diagram illustrating an example of a hardware configuration of the electronic device;

FIG. 3 is a block diagram illustrating a flow of information between a cooling fan control device and a control microcomputer;

FIG. 4 is a diagram illustrating an example of a control characteristic registered in a control table of a cooling fan;

FIG. 5 is a functional block diagram illustrating an example of a functional configuration of the cooling fan control device;

FIG. 6 is a flowchart illustrating an example of a flow of a cooling fan setting process; and

FIG. 7 is a flowchart illustrating an example of a flow of a cooling fan control process.

### DETAILED DESCRIPTION

In general, according to one embodiment, a cooling fan control device and a cooling fan control method capable of controlling an operation of a cooling fan without changing an application program even when the cooling fan is changed are provided.

A cooling fan control device according to an embodiment controls an operation of a cooling fan connected to a control microcomputer by communicating with the control microcomputer, and includes a reading unit, a storage unit, an acquisition unit, and an operation control unit. The reading unit reads a control table of the cooling fan stored in the control microcomputer. The storage unit stores a content of the control table read by the reading unit. The acquisition unit acquires, from the control microcomputer, a current ambient temperature and a current fan speed of the cooling fan. The operation control unit outputs a control command for controlling the cooling fan to the control microcomputer based on the ambient temperature and the fan speed that are acquired by the acquisition unit, and based on the control table.

Hereinafter, an embodiment will be described in detail with reference to the drawings. The present disclosure is not limited to the embodiment described below.

### Embodiment

Hereinafter, an electronic device 1 according to an embodiment of the present disclosure will be described with reference to the drawings.

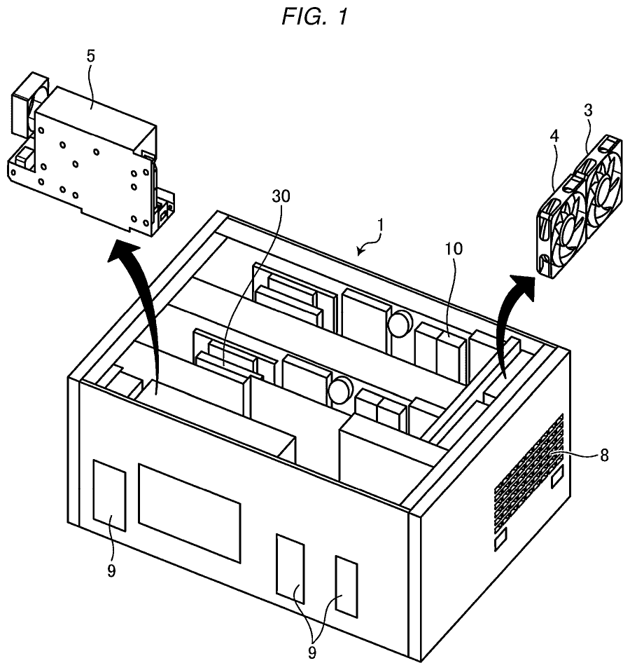

General Configuration of Cooling Fan Control System A schematic configuration of the electronic device 1 according to the embodiment will be described with reference to FIG. 1. FIG. 1 is a perspective view illustrating an example of the electronic device according to the embodiment.

The electronic device 1 performs various types of electronic control in accordance with applications. The electronic device 1 is a point of sales (POS) terminal that performs various processes related to transactions of commodities in a store, a server device that is connected to a plurality of POS terminals, manages the plurality of POS terminals, and performs sales management in the store, or the like. The electronic device 1 is not limited thereto.

The electronic device 1 is accommodated in a housing 2, and includes a control microcomputer 10, a cooling fan control device 30, a cooling fan 3, a cooling fan 4, and a cooling fan 5.

Since the control microcomputer 10 and the cooling fan control device 30 include heating elements such as a CPU and a memory device, it is necessary to appropriately cool the control microcomputer 10 and the cooling fan control device 30 in accordance with an ambient temperature of an inside of the housing 2 in order to stably operate the control microcomputer 10 and the cooling fan control device 30.

The cooling fans 3, 4, and 5 are used for such cooling. The cooling fans 3, 4, and 5 include fans that are driven to rotate by a motor, and cool the inside of the housing 2 by discharging air inside the housing 2 to an outside of the housing 2. The number of cooling fans included in the electronic device 1 is not limited.

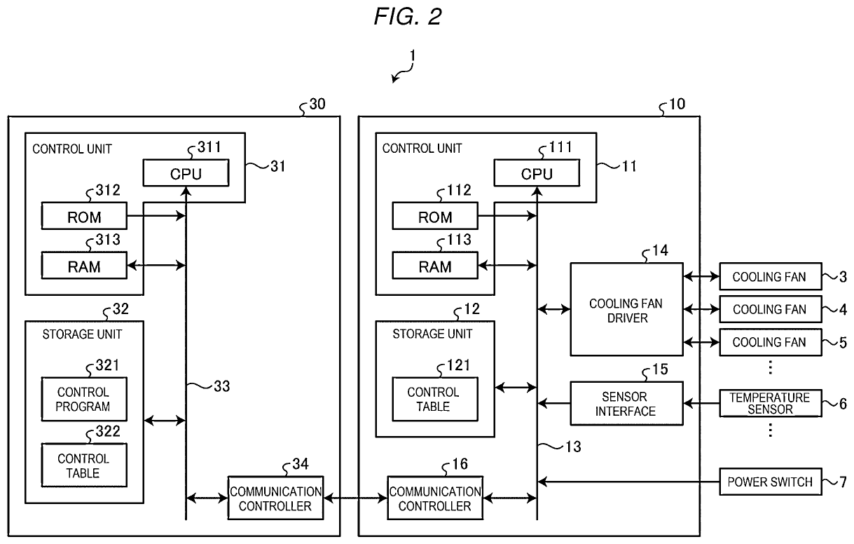

The cooling fan control device 30 acquires, from the control microcomputer 10, a control table 121 (see FIG. 2) in which control characteristics of a plurality of cooling fans including the cooling fans 3, 4, and 5 are described. In addition, the cooling fan control device 30 repeatedly acquires, from the control microcomputer 10, an ambient temperature T of the inside of the housing 2 measured by a temperature sensor 6 to be described later and fan speeds which are rotation speeds of the cooling fans 3, 4, and 5. Further, the cooling fan control device 30 gives a control command for controlling the cooling fans 3, 4, and 5 to the control microcomputer 10 based on the control table 121 of the currently connected cooling fans 3, 4, and 5, the ambient temperature of the inside of the housing 2 acquired from the control microcomputer 10, and the fan speeds of the cooling fans 3, 4, and 5.

The control microcomputer 10 outputs the control table 121 of the cooling fan stored therein to the cooling fan control device 30. Further, the control microcomputer 10 repeatedly outputs, to the cooling fan control device 30, the ambient temperature of the inside of the housing 2 measured by the temperature sensor and the fan speeds of the cooling fans 3, 4, and 5. Further, the control microcomputer 10 receives the control command from the cooling fan control device 30 and controls operations of the cooling fans 3, 4, and 5. Accordingly, the control microcomputer 10, the cooling fan control device 30, and the like are cooled.

On side surfaces of the housing 2, vent holes 8 which are air outlets when air adsorbed by the cooling fans 3, 4, and 5 is discharged to the outside of the housing 2, and connectors 9 which connect the electronic device 1 and a display device such as a monitor or an operation device such as a keyboard (not illustrated) are provided.

### Hardware Configuration of Electronic Device

The hardware configuration of the electronic device 1 will be described with reference to FIG. 2. FIG. 2 is a hardware block diagram illustrating an example of the hardware configuration of the electronic device according to the embodiment.

The electronic device 1 includes the cooling fan control device 30, the control microcomputer 10, the cooling fan 3, the cooling fan 4, the cooling fan 5, the temperature sensor 6, and a power switch 7 that are connected to the control microcomputer 10.

The control microcomputer 10 includes a control unit 11, a storage unit 12, a cooling fan driver 14, a sensor interface 15, and a communication controller 16. The control unit 11, the storage unit 12, the cooling fan driver 14, and the sensor interface 15 are connected by an internal bus 13. The control microcomputer 10 is, for example, a central processing unit (CPU) board.

The control unit 11 controls overall operations of the control microcomputer 10, and the control unit 11 includes a CPU 111, a read only memory (ROM) 112, and a random access memory (RAM) 113. The CPU 111 is connected to the ROM 112 and the RAM 113 via an internal bus such as an address bus and a data bus. The CPU 111 loads a control program stored in the ROM 112 into the RAM 113. The CPU 111 controls the operations of the control microcomputer 10 by operating according to the control program loaded into the RAM 113. That is, the control unit 11 has a configuration of a general computer.

The storage unit 12 is a storage device such as a hard disk drive (HDD) or a solid state drive (SSD) connected to the control unit 11 via the internal bus 13. The storage unit 12 may be a nonvolatile memory such as a flash memory in which stored information is held even when power is turned off. The storage unit 12 stores the control table 121. The storage unit 12 may further store a control program for operating the control unit 11.

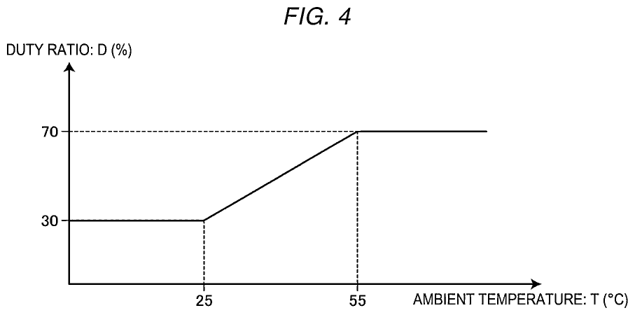

The control table 121 is a table in which the control characteristics of all the cooling fans that have a possibility of connecting to the control microcomputer 10 are described. In the control table 121, identification information for uniquely specifying a type of a cooling fan, such as type information of a cooling fan, and a relationship between the ambient temperature T and the fan speed of the cooling fan are stored in association with each other. The fan speed of the cooling fan is represented by, for example, a duty ratio D of a drive pulse applied to the motor that drives the cooling fan. The control characteristics of the cooling fan will be described later in detail (see FIG. 4).

The cooling fan driver 14 is a drive circuit of the motor that drives the cooling fans 3, 4, and 5. The cooling fan driver 14 may include different drivers for the cooling fans 3, 4, and 5, or one cooling fan driver 14 may drive a plurality of cooling fans.

The sensor interface 15 acquires an output of the temperature sensor 6 provided inside the housing 2 of the electronic device 1, that is, the ambient temperature T of the inside of the housing 2, and transfers the acquired output to the control unit 11.

The temperature sensor 6 is, for example, a thermistor. The thermistor is an element that changes a resistance value itself in accordance with the surrounding ambient temperature. The number of temperature sensors 6 to be provided is not limited. That is, the temperature sensors 6 are provided in respective regions cooled by the cooling fans 3, 4, and 5.

The communication controller 16 receives various types of information between the control microcomputer 10 and the cooling fan control device 30 by controlling communication between the control microcomputer 10 and the cooling fan control device 30.

The control unit 11 of the control microcomputer 10 acquires a signal indicating that the power switch 7 is turned on, and starts operations thereof. Further, the control unit 11 of the control microcomputer 10 acquires a signal indicating that the power switch 7 is turned off, and stops the operations thereof.

The cooling fan control device 30 includes a control unit 31, a storage unit 32, and a communication controller 34. The control unit 31, the storage unit 32, and the communication controller 34 are connected by an internal bus 33.

The control unit 31 controls overall operations of the cooling fan control device 30, and the control unit 31 includes a CPU 311, a ROM 312, and a RAM 313. The CPU 311 is connected to the ROM 312 and the RAM 313 via an internal bus such as an address bus and a data bus. The CPU 311 loads various programs stored in the ROM 312 and the storage unit 32 into the RAM 313. The CPU 311 controls the operations of the cooling fan control device 30 by operating according to various programs loaded into the RAM 313. That is, the control unit 31 has a configuration of a general computer.

The storage unit 32 is a storage device such as an HDD or an SSD connected to the control unit 31 via the internal bus 33. The storage unit 32 may be a nonvolatile memory such as a flash memory in which stored information is held even when power is turned off. The storage unit 32 stores a control program 321 and a control table 322.

The control program 321 is a program for controlling the overall operations of the cooling fan control device 30. The control program 321 may be provided in a state of being stored in the storage unit 32, or may be provided by being recorded in a non-transitory computer-readable recording medium such as a CD-ROM, a flexible disk (FD), a CD-R, or a DVD in a file of an installable format or an executable format. In addition, the control program 321 may be stored in a computer connected to a network and provided by being downloaded via the network. The control program 321 may be provided or distributed via a network such as the Internet.

The control table 322 is the control table 121 read from the control microcomputer 10. That is, the control table 322 and the control table 121 are the same. In order to distinguish the control table stored in the control microcomputer 10 from the control table read by the cooling fan control device 30, different reference numerals are given in the following description.

The communication controller 34 receives various types of information between the cooling fan control device 30 and the control microcomputer 10 by controlling the communication between the cooling fan control device 30 and the control microcomputer 10.

Information Reception between Cooling Fan Control Device and Control Microcomputer

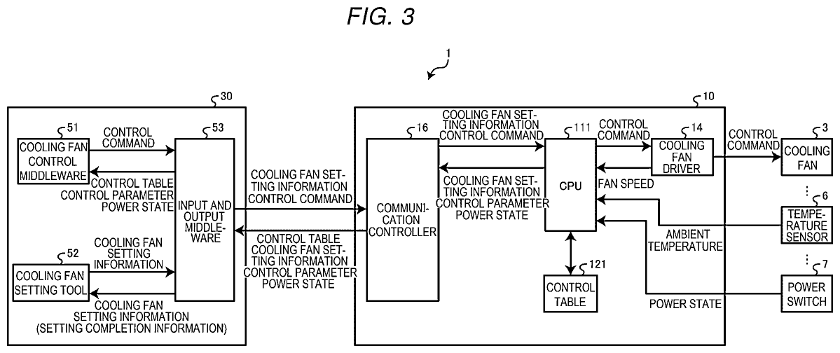

The reception of the various types of information performed between the cooling fan control device 30 and the control microcomputer 10 will be described with reference to FIG. 3. FIG. 3 is a block diagram illustrating a flow of information between the cooling fan control device and the control microcomputer included in the electronic device according to the embodiment.

The control unit 31 of the cooling fan control device 30 includes cooling fan control middleware 51 operated by the CPU 311, a cooling fan setting tool 52, and input and output middleware 53.

The cooling fan control middleware 51 acquires the control table 121 from the control microcomputer 10. The cooling fan control middleware 51 repeatedly acquires control parameters necessary for controlling the cooling fans 3, 4, and 5 from the control microcomputer 10. The control parameters are, for example, the ambient temperature T of the inside of the housing 2 measured by the temperature sensor 6 and the fan speeds of the cooling fans 3, 4, and 5. Further, the cooling fan control middleware 51 acquires a state of the power switch 7 from the control microcomputer 10.

The cooling fan control middleware 51 outputs the control command for controlling the cooling fans 3, 4, and 5 to the control microcomputer 10.

The cooling fan setting tool 52 is a software tool for setting the types of the cooling fans 3, 4, and 5 provided in the electronic device 1. The cooling fan setting tool 52 specifies the cooling fans 3, 4, and 5 connected to the control microcomputer 10, thereby setting a control table to be used as a control target among the control tables 121 stored in the storage unit 12.

The cooling fan setting tool 52 outputs cooling fan setting information for specifying a cooling fan as the control target to the control microcomputer 10. The cooling fan setting tool 52 acquires information (setting completion information) indicating that a setting of the cooling fan is completed from the control microcomputer 10.

The input and output middleware 53 controls inputs and outputs of various types of information between the cooling fan control middleware 51 and the control microcomputer 10 and between the cooling fan setting tool 52 and the control microcomputer 10.

The control microcomputer 10 receives various types of information from the cooling fan control device 30 via the communication controller 16.

The CPU 111 of the control microcomputer 10 accesses the control table 121 stored in the storage unit 12 and outputs contents of the control table 121 to the cooling fan control middleware 51.

When the cooling fan setting information is acquired from the cooling fan setting tool 52, the CPU 111 of the control microcomputer 10 accesses the control table 121 stored in the storage unit 12 and validates the corresponding cooling fan in the control table 121. Then, the CPU 111 returns the setting completion information indicating that the setting of the cooling fan is completed to the cooling fan setting tool 52.

The CPU 111 gives the control command acquired from the cooling fan control middleware 51 to the cooling fan driver 14. The control command is, for example, information for specifying the cooling fan and the duty ratio D of the drive pulse applied to the corresponding cooling fan.

The cooling fan driver 14 generates a pulse waveform of the instructed duty ratio D based on the control command received from the CPU 111, and drives the cooling fan 3 with the generated pulse waveform. The CPU 111 gives a control command to all the cooling fans connected to the control microcomputer 10 via the cooling fan driver 14. The cooling fan driver 14 may be provided for every cooling fan.

The CPU 111 repeatedly acquires the fan speed of the cooling fan 3 via the cooling fan driver 14. Specifically, the CPU 111 repeatedly acquires, from the cooling fan driver 14, the duty ratio D of the drive pulse output to the cooling fan 3. The duty ratio D of the drive pulse indicates the fan speed of the cooling fan 3 at that time. That is, the fan speed increases as the duty ratio D of the drive pulse increases, and the fan speed decreases as the duty ratio D of the drive pulse decreases. The CPU 111 repeatedly acquires the fan speed (duty ratio D) from all the cooling fans connected to the control microcomputer 10. The CPU 111 may acquire the fan speed itself.

Further, the CPU 111 repeatedly acquires the ambient temperature T of the inside of the housing 2 from the temperature sensor 6. Note that, since a plurality of temperature sensors are provided inside the housing 2, the CPU 111 acquires the ambient temperatures T from all the temperature sensors.

The CPU 111 acquires the state of the power switch 7 from the corresponding power switch 7. The state of the power switch 7 is information indicating whether the power switch 7 is turned on or turned off. The CPU 111 may acquire information indicating that the power switch 7 is switched from turning off to turning on and information indicating that the power switch 7 is switched from turning on to turning off, that is, information indicating that the state of the switch changes.

The CPU 111 repeatedly outputs, to the cooling fan control middleware 51, all of the ambient temperatures T of the inside of the housing 2 acquired from the temperature sensors and all of the fan speeds (duty ratios D) of the cooling fans that are in association with acquired time points, respectively. The ambient temperature T is output in association with a value measured by which temperature sensor. The fan speed is output in association with which cooling fan the fan speed is. A time for repeatedly outputting the ambient temperatures T and the fan speeds is set according to processing capacity of the control microcomputer 10.

In addition, the CPU 111 outputs the state of the power switch 7 to the cooling fan control middleware 51.

### Control Characteristics of Cooling Fan

The control characteristics registered in the control table 121 of the cooling fan will be described with reference to FIG. 4. FIG. 4 is a diagram illustrating an example of a control characteristic registered in the control table of the cooling fan.

The cooling fans 3, 4, 5, and so on rotate at fan speeds corresponding to the ambient temperatures T near the cooling fans 3, 4, 5, and so on, thereby cooling the heating elements near the cooling fans 3, 4, 5, and so on. The fan speed is determined by the duty ratio D of the drive pulse applied to the motor that drives the cooling fans 3, 4, 5, and so on to cause the cooling fans 3, 4, 5, and so on to rotate.

The duty ratio D is, for example, a ratio of an ON time p to a time t of one cycle of the drive pulse. That is, D=p/t. As the duty ratio D increases, that is, as the ratio of the ON time p to the time t of one cycle of the drive pulse increases, the fan speed increases.

According to the control characteristics illustrated in FIG. 4, when the ambient temperature T is lower than 25° C., the cooling fan is driven with a drive pulse having a duty ratio D of 30%. When the ambient temperature T is 55° C. or higher, the cooling fan is driven with a drive pulse having a duty ratio D of 70%. Since the fan speed of the cooling fan is substantially proportional to the duty ratio D, in the example of FIG. 4, when the ambient temperature T is 55° C. or higher, the cooling fan rotates at a speed about twice that when the ambient temperature T is lower than 25° C.

When the ambient temperature T is 25° C. or higher and lower than 55° C., the cooling fan is driven with a drive pulse having a value obtained by linearly interpolating the duty ratio D between 30% and 70% in the corresponding range of the ambient temperature T. That is, the duty ratio D is expressed by Formula (1).

$$D = ( 4 T - 10 ) / 3 \qquad ( 1 )$$

The control characteristics of the cooling fans are not limited to the example of FIG. 4, and different control characteristics are set for every cooling fan and stored in the control table 121.

### Functional Configuration of Cooling Fan Control Device

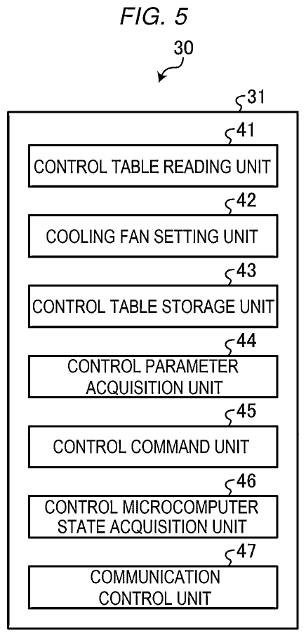

The functional configuration of the cooling fan control device 30 included in the electronic device 1 according to the embodiment will be described with reference to FIG. 5. FIG. 5 is a functional block diagram illustrating an example of the functional configuration of the cooling fan control device included in the electronic device according to the embodiment.

The control unit 31 of the cooling fan control device 30 reads the control program 321, loads the control program 321 into the RAM 313, and executes the control program 321, thereby implementing, as functional units, a control table reading unit 41, a cooling fan setting unit 42, a control table storage unit 43, a control parameter acquisition unit 44, a control command unit 45, a control microcomputer state acquisition unit 46, and a communication control unit 47 illustrated in FIG. 5. All or some of these functional units may be implemented by dedicated hardware.

The control table reading unit 41 reads the control table 121 in which the control characteristics of the cooling fans 3, 4, 5, and so on are described, the control table 121 being stored in the control microcomputer 10. The control table reading unit 41 is an example of a reading unit in the present disclosure.

The cooling fan setting unit 42 sets the control table 121 to be used as the control target by the control command unit 45 from the control tables 121 stored in the control table storage unit 43. The cooling fan setting unit 42 is an example of a setting unit in the present disclosure.

The control table storage unit 43 stores the contents of the control table 121 read by the control table reading unit 41. The control table storage unit 43 is an example of a storage unit in the present disclosure.

The control parameter acquisition unit 44 acquires, from the control microcomputer 10, the ambient temperatures T and the duty ratios D (fan speeds) of the cooling fans 3, 4, 5, and so on that are in association with each other. The control parameter acquisition unit 44 is an example of an acquisition unit in the present disclosure.

The control command unit 45 outputs the control command for controlling the cooling fans 3, 4, 5, and so on to the control microcomputer 10 based on the ambient temperatures T and the duty ratios D (fan speeds) that are acquired by the control parameter acquisition unit 44 and based on the control table 121. The control command unit 45 is an example of an operation control unit in the present disclosure.

The control microcomputer state acquisition unit 46 acquires a power state of the control microcomputer 10.

The communication control unit 47 controls the communication between the control microcomputer 10 and the cooling fan control device 30.

### Flow of Cooling Fan Setting Process Performed by Cooling Fan Control Device

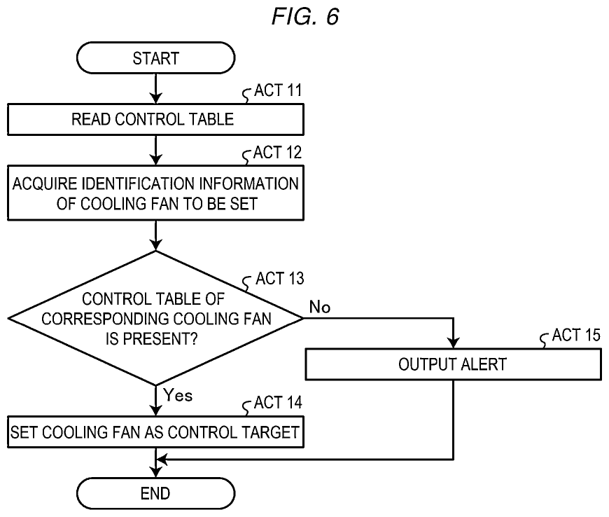

The flow of the cooling fan setting process performed by the cooling fan control device 30 will be described with reference to FIG. 6. FIG. 6 is a flowchart illustrating an example of the flow of the cooling fan setting process performed by the cooling fan control device included in the electronic device according to the embodiment.

An operator starts up the cooling fan setting tool 52 operating in the cooling fan control device 30 to perform the following process.

The control table reading unit 41 reads the control table 121 stored in the storage unit 12 of the control microcomputer 10 (Act 11).

The cooling fan setting unit 42 acquires identification information of the cooling fan to be set as the control target (Act 12). Specifically, the cooling fan setting unit 42 prompts the operator to input information (for example, the type of the cooling fan) for specifying the cooling fan as the control target.

The cooling fan setting unit 42 determines whether the control table of the corresponding cooling fan is present in the control tables 121 read by the control table reading unit 41 (Act 13). When it is determined that the control table of the corresponding cooling fan is present (Act 13: Yes), the process proceeds to Act 14. On the other hand, when it is determined that the control table of the corresponding cooling fan is not present (Act 13: No), the process proceeds to Act 15.

In Act 13, when it is determined that the control table of the corresponding cooling fan is present, the cooling fan setting unit 42 sets the corresponding control table as the control table of the cooling fan as the control target (Act 14). Thereafter, the cooling fan control device 30 ends the process of FIG. 6.

On the other hand, when it is determined in Act 13 that the control table of the corresponding cooling fan is not present, the cooling fan setting unit 42 outputs an alert to indicate that the corresponding control table is not present (Act 15). Thereafter, the cooling fan control device 30 may end the process of FIG. 6, or may return to Act 12 to prompt the operator to input the information again.

When the cooling fan control device 30 controls a plurality of cooling fans, the cooling fan setting tool 52 sets the plurality of cooling fans as the control target in Act 14.

### Flow of Cooling Fan Control Process Performed by Cooling Fan Control Device

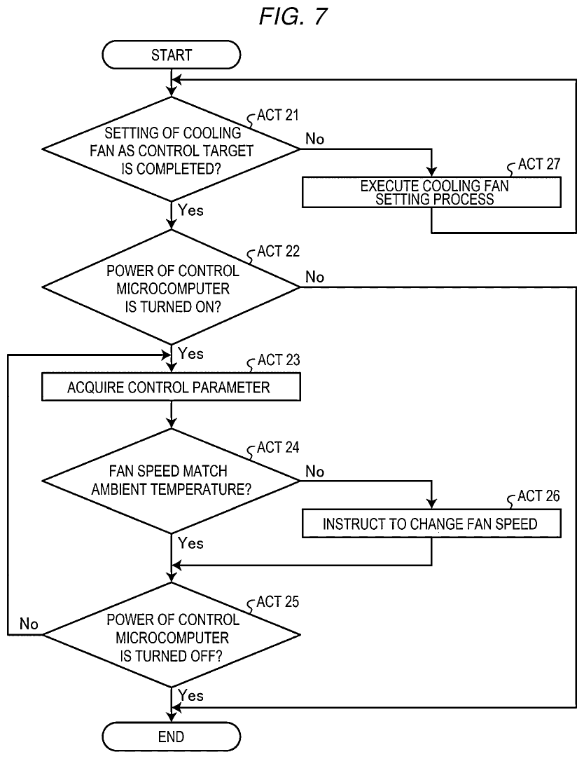

The flow of the cooling fan control process performed by the cooling fan control device 30 will be described with reference to FIG. 7. FIG. 7 is a flowchart illustrating an example of the flow of the cooling fan control process performed by the cooling fan control device included in the electronic device according to the embodiment.

The operator starts up the cooling fan control middleware 51 operating in the cooling fan control device 30 to perform the following process.

The cooling fan setting unit 42 determines whether the setting of the cooling fan as the control target is completed (Act 21). When it is determined that the setting of the cooling fan as the control target is completed (Act 21: Yes), the process proceeds to Act 22. On the other hand, when it is determined that the setting of the cooling fan as the control target is not completed (Act 21: No), the process proceeds to Act 27.

When it is determined in Act 21 that the setting of the cooling fan as the control target is completed, the control microcomputer state acquisition unit 46 determines whether power of the control microcomputer 10 is turned on (Act 22). When it is determined that the power of the control microcomputer 10 is turned on (Act 22: Yes), the process proceeds to Act 23. On the other hand, when it is determined that the power of the control microcomputer 10 is not turned on (Act 22: No), the cooling fan control device 30 ends the process of FIG. 7.

When it is determined in Act 22 that the power of the control microcomputer 10 is turned on, the control parameter acquisition unit 44 acquires the control parameters (the ambient temperature T and the fan speed (duty ratio D)) from the control microcomputer 10 (Act 23).

The control command unit 45 determines whether the fan speed (duty ratio D) acquired in Act 23 matches the ambient temperature T acquired in association with the corresponding fan speed (Act 24). When it is determined that the fan speed matches the ambient temperature T acquired in association with the corresponding fan speed (Act 24: Yes), the process proceeds to Act 25. On the other hand, when it is determined that the fan speed does not match the ambient temperature T acquired in association with the corresponding fan speed (Act 24: No), the process proceeds to Act 26. When the cooling fan control device 30 controls a plurality of cooling fans, the control command unit 45 performs the determination of Act 24 for the cooling fans.

When it is determined in Act 24 that the fan speed does not match the ambient temperature T acquired in association with the corresponding fan speed, the control command unit 45 instructs the control microcomputer 10 to change the fan speed (Act 26). Specifically, the control command unit 45 instructs the control microcomputer 10 to execute the fan speed (duty ratio D) matching the ambient temperature T. Thereafter, the process proceeds to Act 25.

On the other hand, when it is determined in Act 24 that the fan speed matches the ambient temperature T acquired in association with the corresponding fan speed, the control microcomputer state acquisition unit 46 determines whether the power of the control microcomputer 10 is turned off (Act 25). When it is determined that the power of the control microcomputer 10 is turned off (Act 25: Yes), the cooling fan control device 30 ends the process of FIG. 7. On the other hand, when it is determined in Act 25 that the power of the control microcomputer 10 is not turned off (Act 25: No), the process returns to Act 23.

### Effects of Embodiment

As described above, the cooling fan control device 30 according to the embodiment controls the operations of the cooling fans 3, 4, and 5 connected to the corresponding control microcomputer 10 by communicating with the control microcomputer 10, and includes the control table reading unit 41 (reading unit) configured to read the control table 121 in which the control characteristics of the cooling fans 3, 4, and 5 are described, the control table 121 being stored in the control microcomputer 10, the control table storage unit 43 (storage unit) configured to store the contents of the control table 121 read by the control table reading unit 41, the control parameter acquisition unit 44 (acquisition unit) configured to acquire the ambient temperatures T and the fan speeds of the cooling fans 3, 4, and 5 that are in association with each other from the control microcomputer 10, and the control command unit 45 (operation control unit) configured to output the control command for controlling the cooling fans 3, 4, and 5 to the control microcomputer 10 based on the ambient temperatures T and the fan speeds that are acquired by the control parameter acquisition unit 44, and based on the control table 121. Accordingly, even when the cooling fan is changed, the operation of the cooling fan can be controlled without changing an application program.

In the cooling fan control device 30 according to the embodiment, control characteristics of a plurality of cooling fans that have a possibility of connecting to the control microcomputer 10 and identification information of the cooling fans are described in association with each other in the control table 121. Accordingly, the control characteristics of the cooling fans that have the possibility of connecting in addition to the control characteristics of the cooling fans that are actually connected can be stored in advance. Accordingly, when the cooling fan is changed, the control characteristic can be quickly changed.

The cooling fan control device 30 according to the embodiment further includes the cooling fan setting unit 42 (setting unit) configured to set the control table 121 to be used by the control command unit 45 (operation control unit), as the control target, from the control tables 121 stored in the control table storage unit 43 (storage unit) by specifying the cooling fan connected to the control microcomputer 10. Accordingly, the cooling fan as the control target can be easily set.

In the present embodiment, the example in which the cooling fans are controlled by the cooling fan control device 30 is described, but when the control characteristics of the cooling fan are simple, the control microcomputer 10 may directly control the cooling fan. However, even in such a case, when the cooling fan setting tool 52 is set to perform more complicated control, the cooling fan control device 30 is caused to control the cooling fan. In this case, the control performed by the control microcomputer 10 is disabled.

While embodiments have been described, the embodiments have been presented by way of example and are not intended to limit the scope of the disclosure. The novel embodiments can be implemented in various other forms, and various omissions, substitutions, and modifications can be made without departing from the gist of the disclosure. The embodiments and the modifications thereof are included in the scope and the gist of the disclosure, and are included in a scope of the disclosure disclosed in the claims and equivalents thereof.

What is claimed is:

1. A cooling fan control device that controls an operation of a cooling fan connected to a control microcomputer by communicating with the control microcomputer, the cooling fan control device comprising:
a reading component configured to read a control table in which a control characteristic of the cooling fan is described, the control table being stored in the control microcomputer;
a storage component configured to store a content of the control table read by the reading component;
an acquisition component configured to acquire an ambient temperature and a fan speed of the cooling fan that are in association with each other from the control microcomputer; and
an operation controller configured to output a control command for controlling the cooling fan to the control microcomputer based on the ambient temperature and the fan speed that are acquired by the acquisition component, and based on the control table.

2. The cooling fan control device according to claim 1, wherein
control characteristics of a plurality of cooling fans that have a possibility of connecting to the control microcomputer and identification information of the cooling fans are described in association with each other in the control table.

3. The cooling fan control device according to claim 2, further comprising:
a setting component configured to set a control table to be used by the operation controller, as a control target, from the control tables stored in the storage component by specifying the cooling fan connected to the control microcomputer.

4. The cooling fan control device according to claim 1, further comprising:
a temperature sensor to measure the ambient temperature inside the control microcomputer.

5. The cooling fan control device according to claim 1, further comprising:
a plurality of temperature sensors each to measure the ambient temperature at different positions inside the control microcomputer.

6. The cooling fan control device according to claim 1, further comprising:
a plurality of cooling fans connected to the control microcomputer.

7. The cooling fan control device according to claim 1, wherein the fan speed comprises a rotational speed of fan blades of the cooling fan.

8. A cooling fan control method, comprising:
reading a stored control table in which a control characteristic of a cooling fan is described;
storing a content of the read control table;
acquiring an ambient temperature and a fan speed of the cooling fan that are in association with each other; and
outputting a control command for controlling the cooling fan based on the acquired ambient temperature and the acquired fan speed, and based on the control table.

9. The cooling fan control method according to claim 8, wherein
control characteristics of a plurality of cooling fans that have a possibility of connecting to the control microcomputer and identification information of the cooling fans are described in association with each other in the control table.

10. The cooling fan control method according to claim 9, further comprising:
a setting component configured to set a control table to be used by the operation controller, as a control target, from the control tables stored in the storage component by specifying the cooling fan connected to the control microcomputer.

11. The cooling fan control method according to claim 8, further comprising:
measure the ambient temperature inside a control microcomputer comprising the cooling fan.

12. The cooling fan control method according to claim 8, further comprising:
outputting a control command for controlling a plurality of cooling fans based on the acquired ambient temperature and the acquired fan speed, and based on the control table.

13. An electronic device, comprising:
a control microcomputer;
a cooling fan connected with the control microcomputer; and
a cooling fan control device that controls an operation of the cooling fan, the cooling fan control device comprising:
a reading component configured to read a control table in which a control characteristic of the cooling fan is described, the control table being stored in the control microcomputer;
a storage component configured to store a content of the control table read by the reading component;
an acquisition component configured to acquire an ambient temperature and a fan speed of the cooling fan that are in association with each other from the control microcomputer; and
an operation controller configured to output a control command for controlling the cooling fan to the control microcomputer based on the ambient temperature and the fan speed that are acquired by the acquisition component, and based on the control table.

14. The electronic device according to claim 13, wherein
control characteristics of a plurality of cooling fans that have a possibility of connecting to the control microcomputer and identification information of the cooling fans are described in association with each other in the control table.

15. The electronic device according to claim 14, further comprising:
a setting component configured to set a control table to be used by the operation controller, as a control target, from the control tables stored in the storage component by specifying the cooling fan connected to the control microcomputer.

16. The electronic device according to claim 13, further comprising:
a temperature sensor to measure the ambient temperature inside the electronic device.

17. The electronic device according to claim 13, further comprising:
a plurality of temperature sensors each to measure the ambient temperature at different positions inside the electronic device.

18. The electronic device according to claim 13, further comprising:
a plurality of cooling fans connected to the control microcomputer.

19. The electronic device according to claim 13, wherein the fan speed comprises a rotational speed of fan blades of the cooling fan.

20. The electronic device according to claim 13, wherein
the electronic device is one of a point of sales (POS) terminal, a store server, self-checkout terminal, or a settlement device.
